(19) United States
(12) Patent Application Publication
(10) Pub. No.: US 2002/0137310 A1
(43) Pub. Date: Sep. 26, 2002

(54) Method and apparatus for fabricating a semiconductor device

(76) Inventors: Seung-Ki Joo, Seongnam-si (KR); Seok-Woon Lee, Incheon (KR)

Correspondence Address: Jay B. Johnson, Esq., Baker Botts L.L.P., Suite 600, 2001 Ross Avenue, Dallas, TX, 75201-2980, US

(21) Appl. No.: 10/038,990

(22) Filed: Jan. 4, 2002

(30) Foreign Application Priority Data
Jan. 4, 2001 (KR) 2001-385

(51) Int. Cl. C30B 1/00; H01L 21/36; H01L 21/20

(52) U.S. Cl. 438/487; 438/492; 438/486

(57) ABSTRACT

The present invention relates to a method and apparatus for depositing a metal layer inducing crystallization of an amorphous silicon layer in order to fabricate a semiconductor device including a crystalline active layer. Since the metal layer inducing a low temperature crystallization of silicon is deposited while heating the substrate, the metal layer contacting the amorphous silicon forms a metal silicide during the deposition process and the other portions of the metal layer remain in the state of metal. Thus, the non-silicide portion of the metal layer may be selectively removed after deposition and the silicide portion of the metal layer has a high resistance against oxidation.

### TECHNICAL FIELD OF THE INVENTION

The present invention generally relates to a method and apparatus for fabricating a semiconductor device. More particularly, the invention relates to a method and apparatus for depositing a metal layer on an amorphous silicon layer and inducing low temperature crystallization of the amorphous silicon layer in order to provide a semiconductor device having a crystalline silicon active layer.

### BACKGROUND OF THE INVENTION

A thin film transistor (TFT) used for display devices such as liquid crystal display (LCD) and organic electro-luminescent light emitting display (OELD) may be formed by depositing a silicon layer on a transparent substrate such as glass or quartz, forming a gate and a gate electrode on the silicon layer, implanting a dopant in the source and drain regions of the silicon layer, annealing the silicon layer to activate the dopant, and finally forming an insulation layer thereon. An active layer constituting the source, drain, and channel regions of the TFT may be formed by depositing a silicon layer on a transparent substrate such as glass using a chemical vapor deposition (CVD) technique. The silicon layer directly deposited on the substrate by the CVD technique is an amorphous silicon layer, which has relatively low electron mobility. As a display device using thin film transistors requires high operation speed and small-scale structure, the integration degree of its driving integrated circuit becomes higher and the aperture ratio of the pixel region becomes lower. Therefore, it is desirable to enhance the electron mobility of the silicon layer so that the driving integrated circuit may be formed together with the pixel TFTs of the display devices and so that the pixel aperture ratio may be increased. For this purpose, various technologies are being used in order to provide a polycrystalline silicon layer having high electron mobility by crystallizing an amorphous silicon layer by means of thermal treatment.

In order to crystallize amorphous silicon, as is widely known in the art, the amorphous silicon deposited on the substrate should be annealed at a temperature of about 600° C. However, since the crystalline silicon TFT driving an LCD should be formed on a glass substrate, the annealing temperature should be lower than the deformation temperature of the glass substrate, which is about 600° C. In order to solve this technical problem, research has been conducted and a couple of techniques have been proposed to solve the problem.

According to the first technique, the amorphous silicon layer is crystallized by melting a part of the silicon layer by radiating a laser beam onto the amorphous silicon layer. This method heats a part of amorphous silicon layer without excessively increasing the temperature of the entire substrate. Therefore, this method may achieve the crystallization of the silicon layer while avoiding deformation of the substrate. However, this method has problems in that the uniformity of the crystallization and the process yield are low and the manufacturing cost is high.

To overcome the aforementioned disadvantages, a method of inducing crystallization of an amorphous silicon layer at a temperature lower than 500° C. by depositing a metal layer on amorphous silicon is being used. This method is conventionally referred to as metal induced lateral crystallization (MILC). This method crystallizes an amorphous silicon layer by means of furnace annealing after depositing a metal layer facilitating the crystallization of the amorphous silicon on at least a portion of the silicon layer to be crystallized. Using this technique, the problems of the laser radiating method, such as low crystal uniformity and process yield and high manufacturing cost may be avoided and solved.

FIG. 1a to FIG. 1f are cross-sectional views illustrating a conventional process for fabricating a crystalline thin film transistor. In the process, a metal layer is deposited on side portions of an amorphous silicon layer and the amorphous silicon layer is crystallized by MILC induced during a thermal treatment thereof.

First, an amorphous silicon layer 11 is formed on a substrate 10 (FIG. 1a), and a gate insulating layer 12 and a gate electrode 13 are formed on the amorphous silicon layer 11 (FIG. 1b). Then, as shown in FIG. 1c, an impurity such as P or B is doped into the amorphous silicon layer using PH₃ or B₂H₆ as dopant and using the, gate electrode 13 as a mask. This doping process defines the source and the drain regions of the TFT. Then, Ni 141, 142, 143 is deposited to form a metal layer for inducing crystallization of the amorphous silicon, layer at a lower temperature (FIG. 1d). As shown in FIG. 1e, thermal treatment is conducted to crystallize the amorphous silicon and to activate the doped impurity. After the thermal treatment, the remaining Ni (i.e. 151, 152 and 153 in FIG. 1e) is removed. It should be understood that although the Ni layer is depicted with several reference numerals (i.e. 141, 142, 143 in FIG. 1d; 151, 152, 153 in FIG. 1e) the Ni layer is deposited as a continuous layer and the different reference numerals are used to differentiate the respective locations where the Ni layer is deposited. Then, as shown in FIG. 1f, an insulation layer 16 is formed with a silicon oxide or a silicon nitride to cover the entire structure. As shown in FIG. 1g, contact holes are formed in the insulation layer 16 and a metal contact 17 is formed in respective contact holes.

### SUMMARY OF THE INVENTION

As aforementioned, in the prior art shown in FIGS. 1a to 1g, Ni is deposited on the entire area of the substrate, and reacts with the material forming the underlying layer during the thermal treatment process. Thus, the Ni deposited on areas 141, 142 and 143 in FIG. 1d respectively reacts with the gate electrode, amorphous silicon and the substrate during the thermal treatment for the crystallization of the amorphous silicon and the impurity activation, and forms Ni-silicide on areas 151, 152 and 153 in FIG. 1e, respectively. After the thermal treatment, the Ni-silicide on areas 151 and 153 needs to be removed in order to prevent a current leakage. However, it is difficult to remove the remaining Ni component because it has formed a Ni-silicide by reacting with the underlying layer.

Further, in the prior art in FIGS. 1a to 1g, the TFT is exposed to the atmosphere before conducting a thermal treatment after the Ni deposition. This may cause the oxidation of the Ni and cause the deterioration of the MILC quality and characteristics of the TFT. It is an object of the present invention to provide a method and an apparatus for fabricating a TFT by which the metal layer deposited to induce the crystallization of the amorphous silicon layer of the TFT can be easily removed and the oxidation of the metal layer can be prevented.

According to the present invention, a semiconductor device including a crystallized active layer is fabricated by providing a substrate; depositing an amorphous silicon layer on said substrate; and heating said substrate while depositing a metal layer inducing low temperature crystallization of amorphous silicon on at least a portion of said amorphous silicon layer.

While conducting the processes of metal deposition and substrate heating simultaneously, the metal deposited on amorphous silicon layer reacts with the amorphous silicon to initiate the crystallization thereof and forms a metal silicide. On the other hand, the metal deposited on the other areas does not react with other material and remains in the state of metal. Therefore, the portions of metal which did not react with the amorphous silicon may be easily remove by etching after its deposition. Further, the metal deposited on the silicon is not oxidized in the following annealing process because it has formed a metal silicide relatively stable to oxidization.

Additional features and advantages of the present invention will be set forth or will be apparent from below detailed description of the invention. The objectives and other advantages of the invention will be realized and attained by the scheme particularly pointed out in the written description and claims hereof as well as the appended drawings.

### BRIEF DESCRIPTION OF THE DRAWINGS

The embodiments of the present invention will be explained with reference to the accompanying drawings, in which:

FIG. 1a to FIG. 1g are cross-sectional views illustrating a conventional method for fabricating a crystalline TFT using MILC;

FIG. 2a and FIG. 2f are cross-sectional views illustrating the process of fabricating a TFT according to a preferred embodiment of the present invention; and

FIG. 3a to FIG. 3c are cross-sectional views illustrating the process of fabricating a TFT according to alternative preferred embodiments of the present invention.

### DETAILED DESCRIPTION OF THE PREFERRED EMBODIMENTS

Reference will now be made in detail to the preferred embodiments of the present invention, examples of which are illustrated in the accompanying drawings.

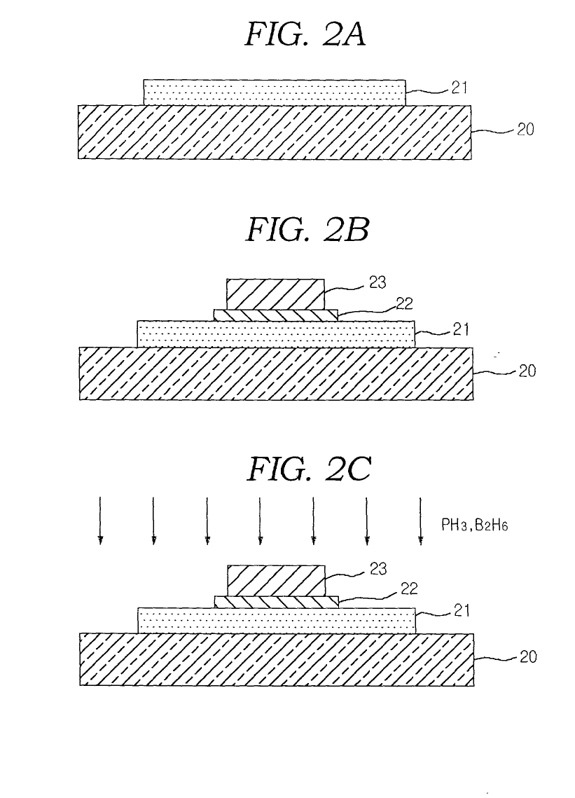

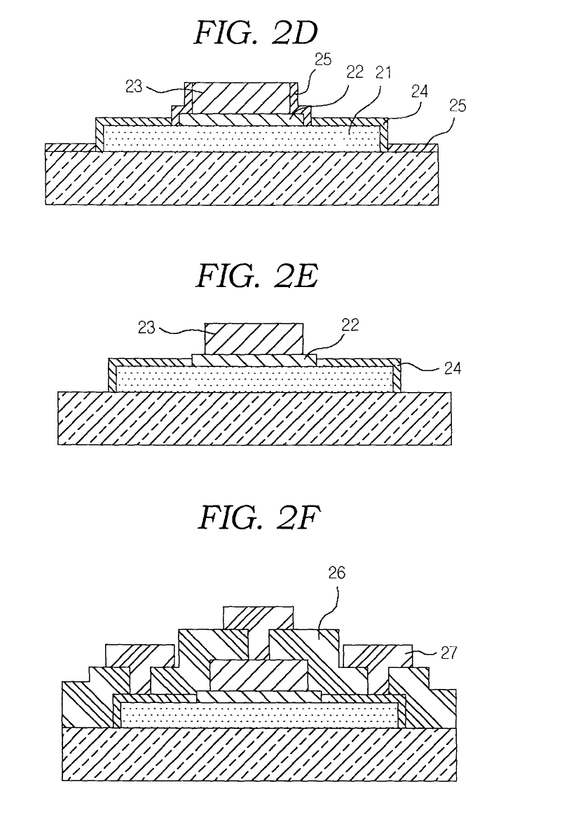

FIG. 2a and FIG. 2f are cross-sectional views illustrating the process of fabricating a TFT according to a preferred embodiment of the present invention. Referring to FIG. 2a, an amorphous silicon layer 21 constituting the active layer of a TFT is formed on substrate 20. Substrate 20 is preferably made of transparent insulator such as Coming 1737 glass, quartz or silicon oxide. According to needs, an optional buffer layer (not shown) may be formed on substrate 20 in order to prevent the diffusion of contaminants from substrate 20. The buffer layer is preferably formed by depositing SiO₂, SiNx, SiOxNy or a combination thereof with a thickness of 300 Å to 10,000 Å, preferably with a thickness in the range of 500 Å to 3,000 Å, at a temperature below 600° C., using various deposition methods such as PECVD (plasma-enhanced chemical vapor deposition), LPCVD (low-pressure chemical vapor deposition), APCVD (atmosphere pressure chemical vapor deposition), ECR CVD (electron cyclotron resonance CVD), and sputtering. The amorphous silicon layer 21 is formed by depositing amorphous silicon with a thickness in the range of 100 Å to 3,000 Å, preferably with a thickness in the range of 500 Å to 1,000 Å, by using a PECVD, LPCVD or sputtering method. This amorphous silicon layer 21 constitutes the active layer of a TFT. The active layer includes source, drain and channel regions and may include additional areas reserved for other devices and electrodes.

Then, as shown in FIG. 2b, a gate insulation layer 22 and a gate electrode 23 are formed on the amorphous silicon layer 21. The gate insulation layer 22 is formed by depositing SiO₂, SiNx, SiOxNy, or a combination thereof, with a thickness in the range of 300 Å to 3,000 Å, preferably with a thickness in the range of 500 Å to 1,000 Å, using various deposition methods such as PECVD, LPCVD, APCVD, and ECR CVD. Then, the gate electrode 23 is formed by depositing a conductive material such as metal or doped poly-silicon on the gate insulation layer 22 by sputtering, heating evaporation, PECVD, LPCVD, APCVD, or ECR CVD. The gate electrode 23 is formed to have a thickness in the range of 1,000 Å to 8,000 Å, preferably with a thickness in the range of 2,000 Å to 4,000 Å.

FIG. 2c is a cross-sectional view illustrating the process of doping the source region and the drain region of the active layer 21 using the gate electrode 23 as a mask. In case of fabricating a NMOS (N-channel metal oxide semiconductor) TFT, the active layer is doped with a dopant such as PH₃, P and As with a dose of 1E11˜1E22/cm³ (preferably 1E15˜1E21/cm³) at the energy level of 10˜200 KeV (preferably 30˜100 KeV) using an ion shower doping method or ion implantation method. In the case of fabricating a PMOS (P-channel metal oxide semiconductor) TFT, the active layer is doped with a dopant such as B₂H₆, B and BH₃ with a dose of M 1E11˜1E22/cm³ (preferably 1E14˜1E21/cm³) at the energy level of 20˜70 KeV. In order to form a lightly-doped region or an offset junction region in the drain region, a low-energy, high-concentration doping and a high-energy, low-concentration doping are conducted in two stages. To fabricate a CMOS, the doping process may be conducted in multiple stages employing additional masks.

In order to crystallize the amorphous silicon layer, a metal layer 25 such as Ni is deposited on the substrate, amorphous silicon and gate electrode and, at the same time, the substrate is heated as shown in FIG. 2d. To induce crystallization of the amorphous silicon, the heating temperature should be over 200° C. and desirably lower than the deformation temperature of the substrate, which is about 650-700° C. The substrate is heated by any method that allows simultaneous metal deposition and substrate heating. For example, a conduction method heating the substrate by contacting a high-temperature body with the substrate or a radiation method heating the substrate using a heating lamp may be effectively used. In the present invention, the metal layer is formed with a thickness of about 20 Å using a low or high pressure CVD, PECVD, sputtering or evaporation method. Although Ni was exemplified above as the source metal inducing the MILC in the amorphous silicon, other metals such as Ti, Ag, Au, Al, Sn, Sb, Cu, Co, Cr, Mo, Tr, Ru, Rh, Cd and Pt or their combinations may also be used.

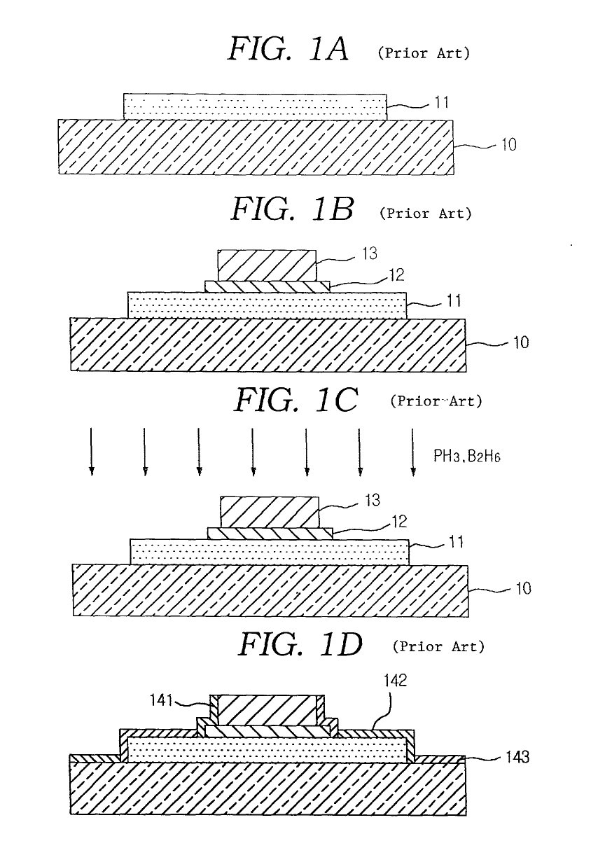

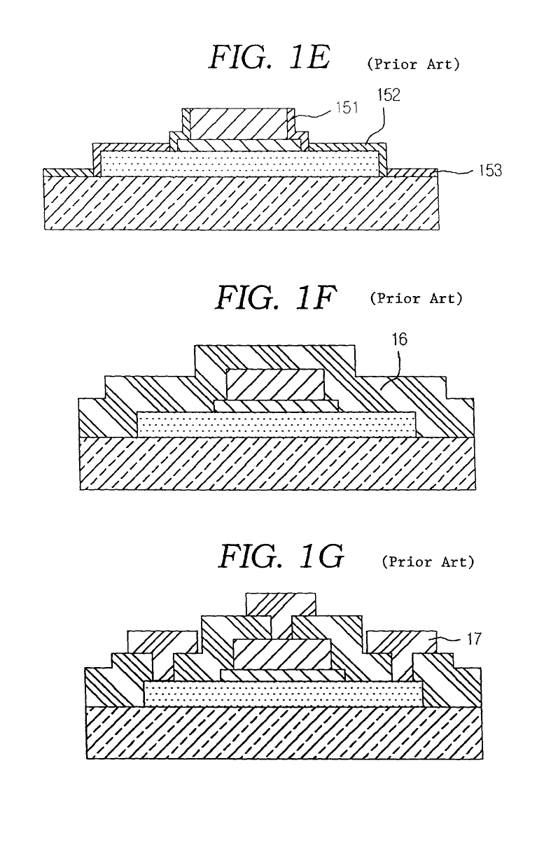

In the present invention, as opposed to the prior technology illustrated in FIG. 1a to FIG. 1g, the substrate is heated for a relatively short time during the deposition of the metal layer. Thus, only a portion of metal layer (i.e., Ni layer) in direct contact with the amorphous silicon reacts with silicon to form a metal silicide (i.e., Ni-silicide) 24 during the metal deposition process. Normally, as will be described below, the crystallization of the amorphous silicon is completed by conducting a separate thermal treatment after the metal deposition. However, depending on the temperature and duration of the metal deposition, a partial crystallization of the amorphous silicon may proceed during the metal deposition process. However, the portions of the metal layer in contact with the substrate 20 and the silicon oxide of the gate insulating layer 22 require a higher reaction energy to form a silicide by reacting with the substrate or the gate insulating layer compared to the case where it reacts with the amorphous silicon 21. Therefore, the Ni deposited on those regions may not form a silicide by the heating conducted during the metal deposition, and thus remains as Ni 25 in a pure state of metal.

The metal layer 25 may be formed to cover the entire surfaces of the substrate and the semiconductor device with a thickness of several Å. Alternatively, the metal layer 25 may be patterned so that a metal offset region is formed between the metal layer and the gate 22, 23. The offset regions may have the same or different widths in the source and drain regions, respectively.

Then, as illustrated in FIG. 2e, the Ni 25 remaining on the gate 22, 23 and the substrate 20 is removed using an etching agent, and a thermal treatment is conducted to induce the crystallization of the amorphous silicon and the impurity activation. During this thermal treatment process, the crystallization of the amorphous silicon initiated in the portion in direct contact with the metal layer 25 propagates into the channel regions under the gate 22, 23 by MILC. As such, the crystallization of the active layer of the TFT is completed. Because the Ni 25 on those regions remains in the state of metal, it may be completely removed by the etching agent. Further, when the Ni is exposed to the atmosphere for conducting a thermal treatment for the crystallization of the amorphous silicon, the Ni is not oxidized because it has already reacted with the silicon to form a silicide. Therefore, the present invention effectively prevents the problems caused by the oxidization of the Ni.

Then, as illustrated in FIG. 2f, a contact insulation layer 26 is formed with an insulating material and contact electrode 27 is formed after forming contact holes in the contact insulation layer 26. Thus, the fabrication process of a TFT according to the present invention is completed.

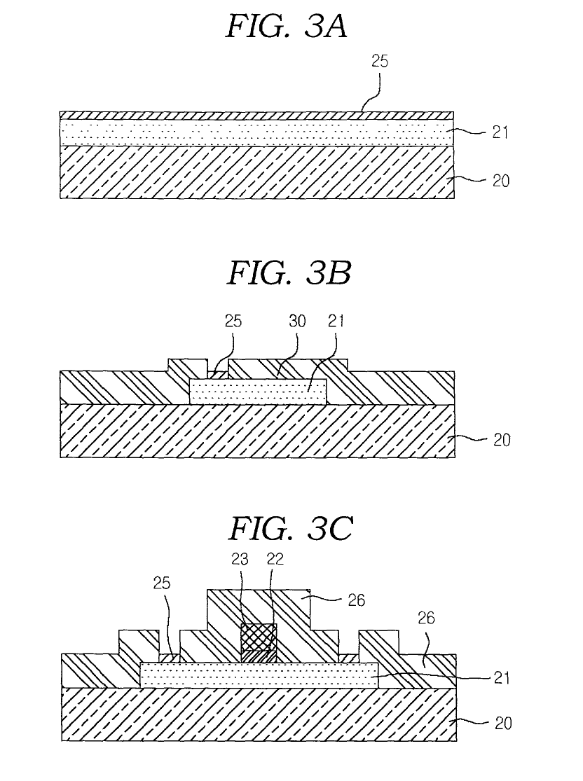

FIG. 3a to FIG. 3e illustrate the process of depositing a metal layer according alternative embodiments of the present invention.

FIG. 3a illustrates a process of crystallizing amorphous silicon layer by metal induced crystallization (MIC). In this embodiment, after forming an amorphous silicon layer 21 on the substrate 20, a metal layer 25 is formed to cover the entire surface of the silicon layer.

Referring to FIG. 3b, an amorphous silicon layer 21 and an insulation layer 30 are sequentially formed on the substrate 20, and an metal layer 25 is deposited after removing a portion of the insulation layer by etching.

Referring to FIG. 3c, an amorphous silicon layer 21, a gate insulation layer 22, a gate electrode and a contact insulation layer 26 are sequentially formed on a substrate 20. Then, a portion of the contact insulation layer 26 is removed to form a contact hole, and a metal layer 25 is formed on the surface of the amorphous silicon exposed though the contact hole.

In the embodiments shown in FIG. 3a to FIG. 3c, the substrate is being heated while depositing a metal layer as explained referring to FIG. 2a to FIG. 2f. When using the methods of FIG. 3a to FIG. 3c, only the portion of the metal layer in direct contact with the amorphous silicon reacts with the amorphous silicon during the metal deposition process to form a metal silicide, and the other portions of the metal do not form a silicide but remain in the state of metal. Therefore, even when the metal is deposited using the methods shown in FIG. 3a to FIG. 3c, the portions of metal remaining in the state of metal may be easily removed by etching. Meanwhile, since the portion of the metal contacting with the silicon forms a silicide, it can prevent the problem that the deposited metal is oxidized when it is exposed to the atmosphere to conduct a thermal treatment for completing the crystallization of the amorphous silicon layer.

As aforementioned, since the present invention heats the substrate while depositing a metal layer inducing a low temperature crystallization of the amorphous silicon, a portion of the metal layer contacting the amorphous silicon reacts with the amorphous silicon during its deposition process and initiates the crystallization of the amorphous silicon by MIC. Meanwhile, the portion of the metal layer contacting with the substrate or the gate structure remains in the state of metal, which facilitates the removal of unnecessary portions of the metal layer after its deposition process. Also, the metal layer contacting with the amorphous silicon is not vulnerable to oxidation because it exists in the state of a silicide. This feature can improve the quality of MIC or MILC induced by the metal layer and eventually improve the characteristics of the TFT fabricated according to the present invention.

Although, the present invention has been described with respect to specific embodiments thereof, various changes and modifications and be carried out by those skilled in the art without departing from the scope of the invention. It is intended, therefore, that the present invention encompass such changes and modifications as fall within the scope of the appended claims.

What is claimed is:

1. A method of fabricating a semiconductor device including a crystallized active layer comprising the steps of:
providing a substrate;
depositing an amorphous silicon layer on said substrate; and
heating said substrate while depositing a metal layer inducing low temperature crystallization of amorphous silicon on at least a portion of said amorphous silicon layer.

2. The method according to claim 1, wherein said metal layer includes at least one element among the group of Ni, Pd, Ti, Ag, Au, Al, Sn, Sb, Cu, Co, Cr, Mo, Tr, Ru, Rh, Cd and Pt.

3. The method according to claim 1, wherein the substrate is heated at a temperature in a range of 200-700° C.

4. The method according to claim 1, wherein said metal layer is deposited using at least one of sputtering, heating evaporation, PECVD and CVD.

5. The method according to claim 1, wherein the substrate is heated by using a heat conduction or a heat radiation method.

6. The method according to claim 1, wherein a portion of said metal layer contacting with said amorphous silicon layer forms a metal silicide.

7. The method according to claim 6, wherein other portions of said metal layer remain in the state of metal and further comprising a step of removing the remaining metal layer by etching.

8. The method according to claim 1, wherein at least a portion of said amorphous silicon layer is crystallized by MIC during the process of heating the substrate while depositing the metal layer.

9. The method according to claim 1, further comprising a step of crystallizing said amorphous silicon layer by conducting a thermal treatment after depositing said metal layer.

10. The method according to claim 1, wherein the step of heating the substrate while depositing the metal layer comprises the steps of:
forming an insulation layer on said substrate and said amorphous silicon layer;
removing a portion of said insulation layer to expose a portion of said amorphous silicon layer; and
depositing said metal layer on the exposed surface of said amorphous silicon layer while heating said substrate.

11. An apparatus for fabricating a semiconductor device including a crystallized active layer comprising:
a means for forming an amorphous silicon layer on a substrate; and
a means for depositing a metal layer inducing low temperature crystallization of amorphous silicon on at least a portion of said amorphous silicon layer while heating said substrate.

12. The apparatus according to claim 11, wherein said metal layer includes at least one element among the group of Ni, Pd, Ti, Ag, Au, Al, Sn, Sb, Cu, Co, Cr, Mo, Tr, Ru, Rh, Cd and Pt.

13. The apparatus according to clam 11, wherein said means for depositing a metal layer and heating the substrate heats the substrate at a temperature in a range of 200-700° C.

14. The apparatus according to claim 11, wherein said metal layer is deposited using at least one of sputtering, heating evaporation, PECVD and CVD.

15. The apparatus according to claim 11, wherein said means for depositing a metal layer and heating the substrate uses a heat conduction or a heat radiation method.
